(19) United States
(12) Patent Application Publication
(10) Pub. No.: US 2026/0177915 A1
(43) Pub. Date: Jun. 25, 2026

(54) PHOTOCURABLE COMPOSITION

(71) Applicants: CANON KABUSHIKI KAISHA, Tokyo (JP); Merck Patent GmbH, Darmstadt (DE)

(72) Inventors: Fen Wan, Austin, TX (US); Weijun Liu, Cedar Park, TX (US); Caroline M. Mccuistion, Austin, TX (US); Gregor Larbig, Darmstadt (DE); Takashi Sekito, Shizuoka (JP)

(21) Appl. No.: 18/990,668

(22) Filed: Dec. 20, 2024

(51) Int. Cl. G03F 7/031; C08F 12/32; G03F 7/00

(52) U.S. Cl. CPC G03F 7/031; C08F 12/32; G03F 7/0002

(57) ABSTRACT

A photocurable composition can comprise a polymerizable material and at least one photoinitiator, wherein the polymerizable material comprises a multi-functional vinylbenzene monomer in an amount of at least 30 wt % based on the total weight of the polymerizable material and the at least one photoinitiator includes an oxime ester compound. The oxime ester compound can have the at least one photoinitiator includes an oxime ester compound having a structure of formula (1):

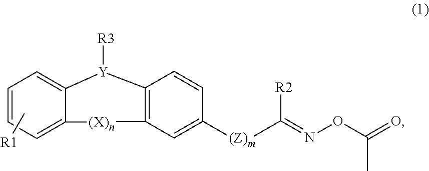

with R1 being H, substituted or unsubstituted alkyl or aryl,

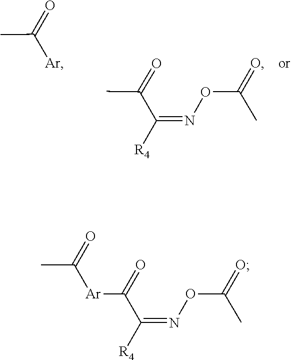

R2 being H or C1-C8 alkyl; R3 being C₄-C₂₀ alkyl or isoalkyl; R4 being H, or alkyl, or aryl; X being S(═O), CH₂, C(═O), O, or NH; n being 0 or 1; Y being N or CH₂; Z being C(═O); m being 0 or 1. The photocurable composition can be adapted that a thermal shrinkage after conducting a baking treatment of the photo-cured layer at 400° C. is not greater than 4.0%.

### FIELD OF THE DISCLOSURE

The present disclosure relates to a photocurable composition, particularly to a photocurable composition adapted for inkjet adaptive planarization.

### BACKGROUND

Inkjet Adaptive Planarization (IAP) is a process which planarizes a surface of a substrate, e.g., a wafer containing an electronic circuit, by jetting liquid drops of a curable composition on the surface of the substrate, and bringing a flat superstrate in direct contact with the added liquid to form a flat liquid layer. The flat liquid layer is typically solidified under UV light exposure, and after removal of the superstrate a planar surface is obtained which can be subjected to subsequent processing steps, for example baking, etching, and/or further deposition steps. There exists a need for improved IAP materials leading to planar cured layers with high thermal stability.

### SUMMARY

In one embodiment, a photocurable composition can comprise a polymerizable material and at least one photoinitiator, wherein the polymerizable material comprises at least one multi-functional vinylbenzene monomer in an amount of at least 30 wt % based on the total weight of the polymerizable material; the at least one photoinitiator includes an oxime ester compound having a structure of formula (1):

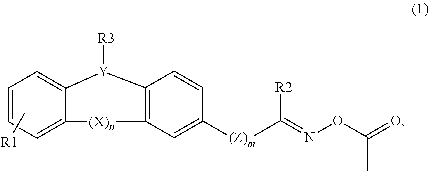

with
R1 being H, substituted or unsubstituted alkyl or aryl,

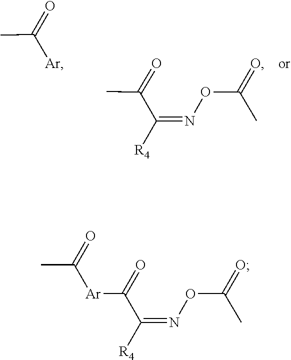

R2 being H or C1-C8 alkyl;
R3 being C₄-C₂₀ alkyl or isoalkyl;
R4 being H, or alkyl, or aryl;
X being S(═O), CH₂, C(═O), O, or NH; n being 0 or 1
Y being N or CH₂;
Z being C(═O); m being 0 or 1.

In one aspect of the photocurable composition, the photoinitiator can have a structure of formula (2):

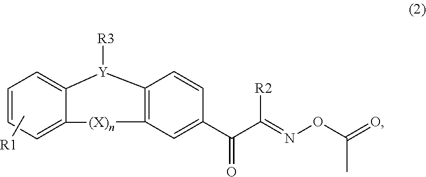

with
R1 being H, or C₁-C₂₀ alkyl or isoalkyl, or

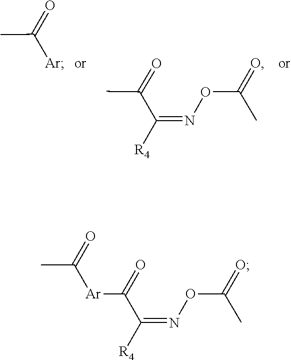

R2 being H or C1-C8 alkyl;
R3 being C4-C20 alkyl or isoalkyl;
R4 being H, or alkyl, or aryl;
Ar being aryl;
X being S(═O), CH₂, C(═O), O, or NH; n being 0 or 1
Y being N or CH₂.

In a particular aspect, the oxime ester compound can have the structure of formula (3):

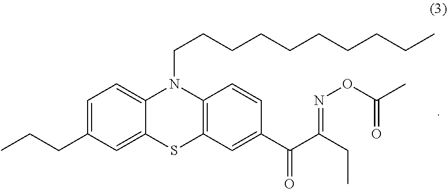 [SMILES: CCCCCCCCCCN1c2ccc(CCC)cc2Sc2cc(C(=O)/C(CC)=N/OC(C)=O)ccc21]

In another particular aspect, the oxime ester may have the structure of formula (4):

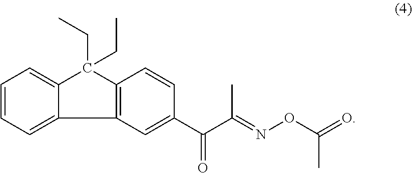 [SMILES: CCC1(CC)c2ccccc2-c2cc(C(=O)/C(C)=N/OC(C)=O)ccc21]

In a further aspect, the photocurable composition can be adapted that a photo-cured layer formed from the photocurable composition has a thermal shrinkage after a baking treatment at 400° C. of not greater than 4.0%, the baking treatment including 2 minutes baking of the photo-cured layer with a thickness of 450-550 nm on a stainless steel plate having a temperature of 400° C. under N₂ environment.

In a certain aspect of the photocurable composition, the oxime ester of formula (1) may not contain fluoride.

In one aspect of the photocurable composition, the amount of the oxime ester compound can be at least 1 wt % and not greater than 7 wt % based on a total weight of the photocurable composition. In a particular aspect, the amount of the oxime ester compound may be at least 3 wt % and not greater than 7 wt % based on the total weight of the photocurable composition.

In another aspect, the at least one photoinitiator of the photocurable composition can further include a photoinitiator not being an oxime ester compound.

In one embodiment of the photocurable composition, the amount of the polymerizable material can be at least 85 wt % based on the total weight of the photocurable composition.

In another embodiment of the photocurable composition, the multi-functional vinylbenzene monomer can include at least three vinyl groups. In one aspect, the multi-functional vinylbenzene monomer can be a biphenyl compound including three vinyl groups.

In another aspect of the photocurable composition, the amount of the multi-functional vinylbenzene monomer can be at least 50 wt % based on the total weight of the polymerizable material.

In a further aspect, the material after photo-curing the photocurable composition can have an onset degradation temperature of at least 400° C.

In one aspect, the polymerizable material of the photocurable composition can further include at least one multi-functional acrylate monomer.

In another aspect, the viscosity of the photocurable composition can be not greater than 50 mPa·s.

In one embodiment, a method of forming a photo-cured layer on a substrate can comprise:
applying a layer of a photocurable composition on the substrate, wherein the photocurable composition comprises a polymerizable material and at least one photoinitiator, wherein the polymerizable material comprises at least one multi-functional vinylbenzene monomer in an amount of at least 30 wt % based on the total weight of the polymerizable material, and the at least one photoinitiator includes an oxime ester compound having a structure of formula (1):

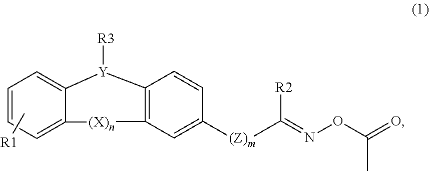

with R1 being H, or substituted or unsubstituted alkyl or aryl; R2 being H or C₁-C₈ alkyl; R3 being C₄-C₂₀ alkyl or isoalkyl; X being S(═O), CH₂, C(═O), O, or NH; n being 0 or 1; Y being N or CH₂; Z being C(═O); m being 0 or 1;
bringing the photocurable composition into contact with a template or a superstrate;
irradiating the photocurable composition with light to form a photo-cured layer; and
removing the template or the superstrate from the photo-cured layer.

In one aspect of the method, the photo-cured layer can have a thermal shrinkage after a baking treatment at 400° C. of not greater than 4.0%, the baking treatment including 2 minutes baking of the photo-cured layer having a thickness of 50 nm to 550 nm under N₂ on a stainless steel plate having a temperature of 400° C.

In another aspect of the methos, the photo-cured layer can have an onset degradation temperature of at least 400° C.

In a further embodiment, a method of manufacturing an article can comprise:
applying a layer of a photocurable composition on the substrate, wherein the photocurable composition may comprise a polymerizable material and at least one photoinitiator, the polymerizable material comprising at least one multi-functional vinylbenzene monomer in an amount of at least 30 wt % based on the total weight of the polymerizable material and at least one photoinitiator, the polymerizable material comprises at least one multi-functional vinylbenzene monomer in an amount of at least 30 wt % based on the total weight of the polymerizable material; and the at least one photoinitiator includes an oxime ester compound having a structure of formula (1):

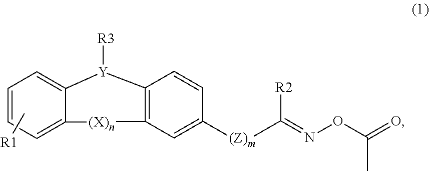

with R1 being H, or substituted or unsubstituted alkyl or aryl; R2 being H or C1-C8 alkyl; R3 being C₄-C₂₀ alkyl or isoalkyl; X being S(═O), CH₂, C(═O), O, or NH; n being 0 or 1; Y being N or CH₂; Z being C(═O); m being 0 or 1;
bringing the photocurable composition into contact with a template or a superstrate;
irradiating the photocurable composition with light to form a photo-cured layer;
removing the template or the superstrate from the photo-cured layer;
forming a pattern on the substrate;
processing the substrate on which the pattern has been formed in the forming; and
manufacturing an article from the substrate processed in the processing.

### BRIEF DESCRIPTION OF THE DRAWING

Embodiments are illustrated by way of example and are not limited in the accompanying figures.

FIG. 1 includes a graph illustrating the weight loss with increasing temperature measured via dynamic thermogravimetry (TGA) of a photocured layer according to one embodiment.

Skilled artisans appreciate that elements in the figures are illustrated for simplicity and clarity and have not necessarily been drawn to scale. For example, the dimensions of some of the elements in the figures may be exaggerated relative to other elements to help improve understanding of embodiments of the invention.

### DETAILED DESCRIPTION

The following description is provided to assist in understanding the teachings disclosed herein and will focus on specific implementations and embodiments of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the imprint and lithography arts.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus.

As used herein, and unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

The present disclosure is directed to a photocurable composition comprising a polymerizable material and a photoinitiator, wherein the polymerizable material can comprise a multi-functional vinylbenzene monomer in an amount of at least 30 wt %, and the photoinitiator can include an oxime ester having a structure of formula (1):

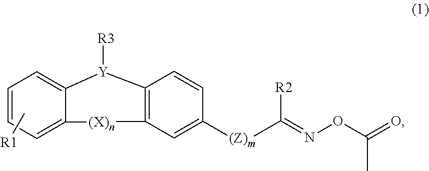

with
R1 being H, substituted or unsubstituted alkyl or aryl,

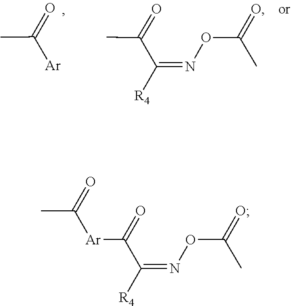

R2 being H or C1-C8 alkyl;
R3 being C₄-C₂₀ alkyl or isoalkyl;
R4 being H, or alkyl, or aryl;
X being S(═O), CH₂, C(═O), O, or NH; n being 0 or 1
Y being N or CH₂;
Z being C(═O); m being 0 or 1.

It has been surprisingly found that the photocurable composition of the present disclosure can have an exceptional high thermal stability and being suitable for inkjet adaptive planarization (IAP) processing.

In one embodiment, the photocurable composition can be adapted that a photo-cured layer formed from the photocurable composition can have a thermal shrinkage after a baking treatment at 400° C. of not greater than 4.0%. As used herein, the thermal shrinkage is defined as the linear shrinkage in the thickness direction of the photo-cured layer after a baking treatments, wherein the photo-cured layer has a thickness of 450-550 nm, and the baking treatment is conducted for 2 minutes on a stainless steel plate having a temperature of 400° C. The linear shrinkage (thermal shrinkage) is calculated as shrinkage (Sₜₕ [%]) according to the following equation: Sₜₕ=[(Tₚ−T_{c})/Tₚ]*100%, with Tₚ being the thickness of the photo-cured layer before the heating treatment, and T_{c} being the thickness of the photo-cured film after the heating treatment. In a particular aspect, the thermal shrinkage may be not greater than 6.0%, or not greater than 4.5%, or not greater than 3.0%, or not greater than 2.5%, or not greater than 2.0%, or not greater than 1.5%.

In one embodiment, the oxime ester compound of the photoinitiator of the present disclosure can have a structure of formula (2):

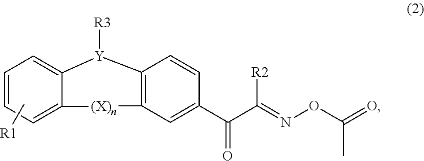

with
R1 being H, or C₁-C₂₀ alkyl or isoalkyl, or

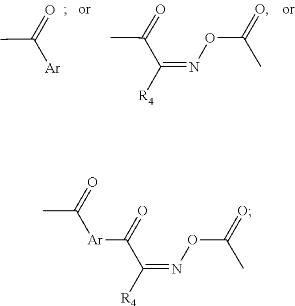

R2 being H or C1-C8 alkyl;
R3 being C4-C20 alkyl or isoalkyl;
R4 being H, or alkyl, or aryl;
Ar being aryl;
X being S(═O), CH₂, C(═O), O, or NH; n being 0 or 1; and Y being N or CH₂.

In a particular aspect, the structure of formula (2) can have R1 being H or C₁-C₁₀ alkyl, R2 being H or C₁-C₈ alkyl, and R3 being C₄-C₁₅ alkyl or isoalkyl, X being N or C, Y being S, and n being 0 or 1.

In one certain aspect, the oxime ester compound can have the structure of formula (3):

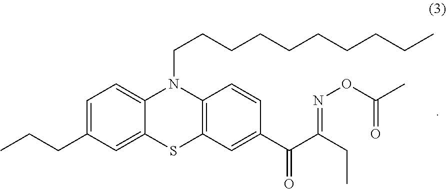 [SMILES: CCCCCCCCCCN1c2ccc(CCC)cc2Sc2cc(C(=O)/C(CC)=N/OC(C)=O)ccc21]

In another certain aspect, the oxime ester compound may have the structure of formula (4):

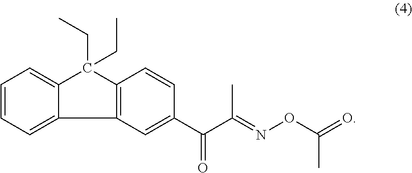 [SMILES: CCC1(CC)c2ccccc2-c2cc(C(=O)/C(C)=N/OC(C)=O)ccc21]

The amount of the oxime ester compound of the photoinitiator can be at least 1.0 wt % based on the total weight of the photocurable composition, or at least 1.5 wt %, or at least 2.0 wt %, or at least 2.5 wt %, or at least 3.0 wt %, or at least 4.0 wt %, or at least 6.0 wt %. In another aspect, the amount of the oxime ester compound may be not greater than 10 wt % based on the total weight of the photocurable composition, or not greater than 8 wt %, or not greater than 7 wt %, or not greater than 6 wt %. The amount of the oxime ester compound of the photoinitiator can be a value between any of the minimum and maximum numbers noted above.

In a certain aspect, the photoinitiator of the photocurable composition can further include at least one photoinitiator which is not an oxime ester compound.

The polymerizable material of the photocurable composition can be a major amount of the composition. In one embodiment, the amount of the polymerizable material can be at least 60 wt % based on the total weight of the photocurable composition, or at least 70 wt %, or at least 80 wt %, or at least 90 wt %, or at least 92 wt %, or at least 95 wt %.

As used herein, the term multi-functional vinylbenzene monomer of the polymerizable material relates to a polymerizable monomer containing one or more benzene rings and at least two vinyl groups directly attached to the one or more benzene rings. In certain aspects, the multi-functional vinylbenzene monomer can comprise at least three vinyl groups or at least four vinyl groups. In a particular aspect, the multi-functional vinylbenzene monomer can comprise two benzene rings and three vinyl groups attached to the benzene rings. A non-limiting example of such monomer can be 3,4′,5-trivinyl-1,1′biphenyl (3VPH).

In one embodiment, the amount of the multi-functional vinylbenzene monomer can be at least 30 wt % based on the total weight of the polymerizable material, such at least 40 wt %, at least 50 wt %, at least 60 wt %, at least 70 wt %, at least 80 wt %, at least 90 wt %, or at least 95 wt %. In another aspect, the amount of the multi-functional vinylbenzene monomer may not greater than 98 wt % based on the total weight of the polymerizable material, or not greater than 95 wt %, or not greater than 90 wt %, or not greater than 80 wt %, or not greater than 70 wt %, or not greater than 60 wt %, or not greater than 50 wt %. The amount of the multi-functional vinylbenzene monomer can be a value between any of the minimum and maximum numbers noted above.

In a certain particular aspect, the polymerizable material can consist essentially of the multi-functional vinylbenzene monomer. As used herein, consisting essentially of the multi-functional vinylbenzene monomer means that not more than 5 wt % of the polymerizable material include other types of polymerizable monomers or polymerizable oligomers.

In another embodiment, the polymerizable material can further comprise a multi-functional acrylate monomer. In one aspect, the multi-functional acrylate monomer can include at least two acrylate groups, or at least three acrylate groups, or at least four acrylate groups. In another aspect, the multi-functional acrylate monomer can include at least one acrylate group and at least one vinyl group. As used herein, the term acrylate monomer relates to substituted and non-substituted acrylate monomers. Non-limiting examples of substituted acrylate monomers can be C₁-C₈ alkylacrylate, for example, methacrylate or ethylacrylate. Furthermore, as used herein, the term “vinyl group” does not relate to a vinyl group which is part of an acrylate group and is a functional group by itself. In a particular aspect, the multi-functional acrylate monomer can include one acrylate group and two vinyl groups and an aromatic ring structure, for example, one or more benzene rings.

The amount of the multi-functional acrylate monomer can be at least 5 wt % based on the total weight of the polymerizable material, or at least 10 wt %, or at least 20 wt %, or at least 30 wt %, or at least 40 wt %, or at least 50 wt %. In another aspect, the amount of the multi-functional acrylate monomer may be not greater than 70 wt % based on the total weight of the polymerizable material, or not greater than 60 wt %, or not greater than 40 wt %. The amount of the multi-functional acrylate monomer can be a value between any of the minimum and maximum numbers noted above.

In another aspect, the polymerizable material can include next to the multi-functional vinylbenzene monomer and the multi-functional acrylate monomer other types of polymerizable compounds, for example, mono-functional monomers, or polymerizable oligomers, or polymerizable polymers. An amount of the other polymerizable compounds can be at least 1 wt % based on the total weight of the polymerizable material, or at least 5 wt %, or at least 10 wt %. In another aspect, the amount of other polymerizable compounds may not be greater than 30 wt %, or not greater than 20 wt %, or not greater than 15 wt %, or not greater than 10 wt %.

In a particular aspect, the photocurable composition can be essentially free of a maleimide monomer. Essentially free of a maleimide monomer means herein that not more than 0.5 wt % of the polymerizable material may be a maleimide monomer. In another aspect, the photocurable composition can be free of a maleimide monomer.

In order to stabilize the multi-functional vinylbenzene monomer in the photocurable composition (preventing unwanted polymerization during storage), a suitable stabilizer can be added to the composition. In one aspect, the photocurable composition can include 4-tert-butylcatechol (TBC) as a stabilizer in an amount of at least 5 ppm based on the total weight of the photocurable composition. In certain aspects, the amount of TBC can be at least 10 ppm based on the total weight of the photocurable composition, or at least 50 ppm, or at least 200 ppm. In another aspect, the amount of TBC may be not greater than 0.1 wt % based on the total weight of the photocurable composition, or than 0.05 wt %, or not greater than 0.03 wt %, or not greater than 0.02 wt %.

In a certain embodiment, the photocurable composition of the present disclosure can be essentially free of a solvent.

As used herein, if not indicated otherwise, the term solvent relates to a compound which can dissolve or disperse the polymerizable monomers but does not itself polymerize during the photo-curing of the photocurable composition. The term “essentially free of a solvent” means herein an amount of solvent being not greater than 7 wt % based on the total weight of the photocurable composition. In a certain particular aspect, the amount of a solvent can be not greater than 5 wt %, not greater than 2 wt %, not greater than 1 wt %, or the photocurable composition can be free of a solvent, except for unavoidable impurities.

In another aspect, the photocurable composition and the present disclosure can comprise a solvent in an amount higher than 5 wt % based on the total weight of the photocurable composition. In a particular aspect, the amount of solvent can be at least 7 wt % based on the total weight of the photocurable composition, or at least 10 wt %, or at least 15 wt %, at least 20 wt %, or at least 25 wt %. In another aspect, the amount of solvent may be not greater than 40 wt %, or not greater than 30 wt %, or not greater than 20 wt %, or not greater than 10 wt % based on the total weight of the photocurable composition.

In a further aspect, the photocurable composition of the present disclosure can be essentially free of particles, for example pigment particles. As used herein, being essentially free of particles means that the photocurable composition contains not more than 50 particles per ml having a size of at least 200 nm, or not more than 50 particles per ml having a size of at least 150 nm, or not more than 50 particles per ml having a size of at least 100 nm, or not more than 50 particles per ml having a size of at least 50 nm, or not more than 50 particles having a size of at least 20 nm, or not more than 50 particles per ml having a size of at least 10 nm.

In one embodiment, the curable composition of the present disclosure can have a low viscosity which may allow the use of these compositions in IAP applications. In one aspect, the viscosity of the curable composition at a temperature of 23° C. can be not greater than 50 mPa·s, such as not greater than 40 mPa·s, or not greater than 30 mPa·s, not greater than 20 mPa·s, not greater than 15 mPa·s. In another aspect, the viscosity may be at least 5 mPa·s, or at least 7 mPa's, or at least 10 mPa·s. As used herein, all viscosity values relate to viscosities measured at a given temperature with the Brookfield method.

In a further aspect, the photocurable composition can contain at least one optional additive. Non-limiting examples of optional additives can be surfactants, dispersants, stabilizer, co-solvents, initiators, inhibitors, dyes, or any combination thereof.

In yet another aspect, a material obtained after photo-curing the photocurable composition (herein also called photo-cured layer) can have an onset degradation temperature (Td) of at least 350° C., or at least 400° C., or at least 450° C., or at least 470° C. In a further aspect, the onset degradation temperature after photo-curing may be not greater than 550° C., or not greater than 500° C.

In another embodiment, the present disclosure is directed to a laminate comprising a substrate and a photo-cured layer overlying the substrate, wherein the photo-cured layer can be formed from the photocurable composition described above.

In a certain aspect, the laminate can further include one or more layers between the substrate and the cured layer, for example an adhesion layer.

The present disclosure is further directed to a method of forming a photo-cured layer. The method can comprise applying the photocurable composition described above on a substrate; bringing the photocurable composition into contact with a template or superstrate; irradiating the photocurable composition with light to form the photo-cured layer; and removing the template or superstrate from the photo-cured layer.

In one aspect, the light irradiation can be conducted with light having a wavelength between 250 nm to 760 nm. In a preferred aspect, the light irradiation may be conducted with light having a wavelength between 300 nm and 400 nm.

The substrate and the solidified (photo-cured) layer may be subjected to additional processing to form a desired article, for example, by including an etching process to transfer an image into the substrate that corresponds to the pattern in one or both of the solidified layer and/or patterned layers that are underneath the solidified layer. The substrate can be further subjected to known steps and processes for device (article) fabrication, including, for example, curing, oxidation, layer formation, deposition, doping, planarization, etching, formable material removal, dicing, bonding, and packaging, and the like. In a certain aspect, the substrate may be processed to produce a plurality of articles (devices).

The cured layer may be further used as an interlayer insulating film of a semiconductor device, such as LSI, system LSI, DRAM, SDRAM, RDRAM, or D-RDRAM, or as a resist film used in a semiconductor manufacturing process.

As further demonstrated in the examples, it has been surprisingly found that photocurable compositions including certain combinations of an oxime ester compound as photoinitiator and multi-functional vinylbenzene as part of the polymerizable material can be very suitable for IAP processing. It was possible to balance parameters important for IAP processing, such as a low viscosity, UV curing speed, and high heat stability after curing in order to make downstream processes possible at temperatures, such as 350° C., or 400° C., or even 450° C.

### EXAMPLES

The following non-limiting examples illustrate the concepts as described herein.

### Example 1

### Preparing of Photocurable IAP Compositions

A set of photocurable compositions was prepared comprising 100 parts by weight 3,5,3′-vinyldiphenylmethane (TVPM) from EMD, 3 parts by weight of the surfactant SA3070, and 3 parts toluene. The compositions were varied by using different types and amounts of oxime ester photoinitiators.

The following oxime ester photoinitiators were used. Comparative compositions C1 to C8 contained oxime esters which are not falling under the present invention: OXE02, TR-PBG-314, TR-TBG-345, TR-PBG-3057, NCL-831E, and OXE03. A summary of all compositions showing the chemical structures of the oxime esters used as photoinitiator and the amount is shown in Table 1.

TABLE 1

| | | Amount of PI |
|---|---|---|
| | | [parts]/ |
| Sample | Structure of PI | Therm. Shr. |
| S1/S2 | 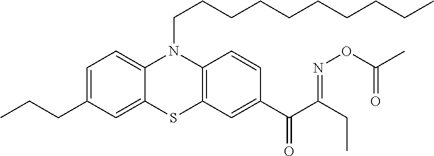 [SMILES: CCCCCCCCCCN1c2ccc(CCC)cc2Sc2cc(C(=O)/C(CC)=N/OC(C)=O)ccc21] | 4/6 2.54%/1.25% |
| S3/S4 | 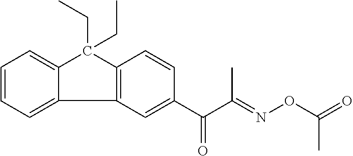 [SMILES: CCC1(CC)c2ccccc2-c2cc(C(=O)/C(C)=N/OC(C)=O)ccc21] | 4/6 3.71%/1.50% |
| C1 | 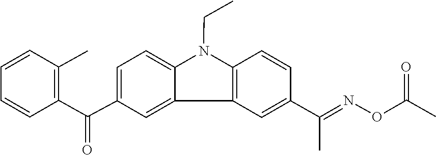 [SMILES: CCn1c2ccc(C(=O)c3ccccc3C)cc2c2cc(/C(C)=N/OC(C)=O)ccc21] | 6 6.30% |
| C2 | 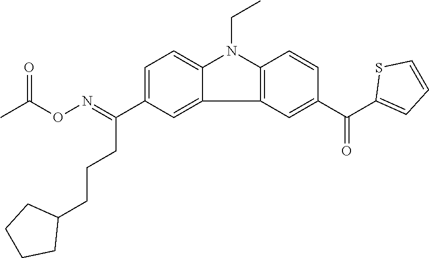 [SMILES: CCn1c2ccc(C(=O)c3cccs3)cc2c2cc(/C(CCCC3CCCC3)=N/OC(C)=O)ccc21] | 4 4.95% |
| C3 | 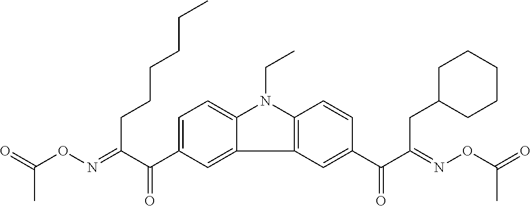 [SMILES: CCCCCC/C(=N\OC(C)=O)C(=O)c1ccc2c(c1)c1cc(C(=O)/C(CC3CCCCC3)=N/OC(C)=O)ccc1n2CC] | 4 8.88% |
| C4 | 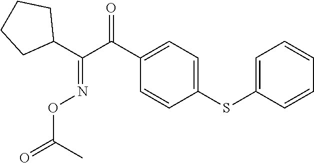 [SMILES: CC(=O)O/N=C(/C(=O)c1ccc(Sc2ccccc2)cc1)C1CCCC1] | 4 5.97% |
| C5 | 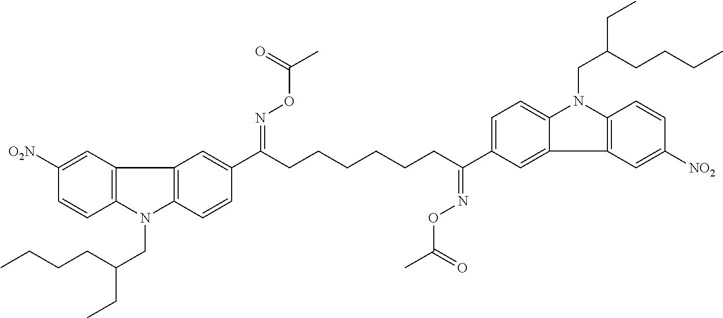 [SMILES: CCCCC(CC)Cn1c2ccc(/C(CCCCCC/C(=N\OC(C)=O)c3ccc4c(c3)c3cc([N+](=O)[O-])ccc3n4CC(CC)CCCC)=N/OC(C)=O)cc2c2cc([N+](=O)[O-])ccc21] | 4 8.27% |
| C6/ C7/ C8 | 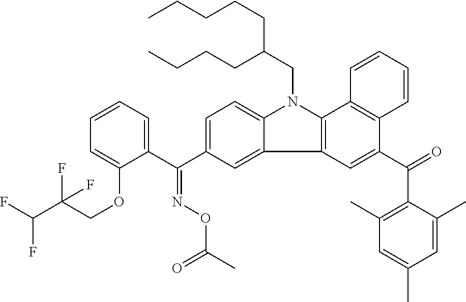 [SMILES: CCCCCC(CCCC)Cn1c2ccc(/C(=N\OC(C)=O)c3ccccc3OCC(F)(F)C(F)F)cc2c2cc(C(=O)c3c(C)cc(C)cc3C)c3ccccc3c21] | 2/4/55 2.7%/1.74%/0.74% |

### Thermal Shrinkage

The thermal shrinkage was determined according to the following procedure:

First, a UV-cured layer was prepared by depositing an about 500 nm thick liquid film of the photocurable composition onto a silicon (Si) wafer by pressing with a blank fused silica template. unto a blank fused silica template. The liquid film was radiated for 50 seconds with UV light having a wavelength of 365 nm and a light intensity of 100 mW/cm², such that the total of curing energy dosage was 5 J/cm², using a DYMAX Bluellave AX-550.

The photo-cured film was subjected to a high temperature baking treatment by placing the UV-cured film for two minutes on a hot plate having a temperature of 400° C. under nitrogen. The thickness of the film before and after the baking was measured with a JA Woollam Spectroscopic Ellipsometer M-2000 X-210. The thermal shrinkage (St) was calculated according to the equation: St=(Tᵤ−T_{b})/Tᵤ, with Tᵤ being the thickness of the photo-cured film before the baking, T_{b} being the thickness of the film after baking.

The measured thermal shrinkage values are also summarized in Table 1. It can be seen that a thermal shrinkage below 4% could only be obtained with samples S1 and S2, or comparative samples C6, C7, and C8.

Not being bound to theory, the advantage of the oxime ester photoinitiators of formula used in the photocurable compositions of samples S1 to S4 2 in comparison to the oxime esters used in comparative examples C1 to C5 may be the selections of the substitution at position R3 in the structured of formula (1), wherein R3 is C4-C20 alkyl or isoalkyl. It was a surprising observation that if R3 of the oxime ester photoinitiator is smaller, such as methyl or ethyl, the thermal shrinkage after the photo-cured layers was higher.

The results further show that the oxime ester photoinitiators of samples S1 to S4 caused a similar reactivity during photocuring (as evidenced by similar thermal shrinkage) as the fluorinated oxime ester OXE02 used in comparative samples C6, C7, and C8. Accordingly, it was possible to obtain photo-cured layers with high thermal stability by using photocurable compositions which were free of fluorine, by using the oxime ester photoinitiators of formula (3) and (4).

### Viscosities

The viscosities of the photocurable compositions were measured using a Brookfield Viscometer LVDV-II+Pro at 200 rpm, with a spindle size #18 and a spin speed of 135 rpm. For the viscosity testing, about 6-7 mL of sample liquid was added into the sample chamber, enough to cover the spindle head. The sample contained in the chamber was about 20 minutes equilibrated to reach the desired measuring temperature of 23° C. before the actual measurement was started. For all viscosity testing, at least three measurements were conducted and an average value was calculated.

The measured viscosities for photocurable compositions S1 and S2 were 28 mPa·s and 32 mPa·s, respectively.

### Example 2

### Thermogravimetric Analysis.

Photo-cured films of samples S1, S3, and C3 were made as described in Example 1, except that the thickness of the layers (films) was about 200 microns after curing, and using a total UV dosage of 20 J (radiating each side with 10 J). The photo-cured layers were investigated via dynamic and isothermal thermogravimetric analysis (TGA) to evaluate the thermal stability of these layers. For the TGA measurements, a STA 6000 Simultaneous Thermal Analyzer, with accessories and Pyris Thermal Analysis Manager Software from Perkin Elmer U.S. LLC. was used. All measurements were conducted under nitrogen at a rate of 5 liter per hour.

### Dynamic Thermogravimetry:

For the dynamic TGA measurements, 25-35 mg of the photo-cured layer was placed in a crucible and the initial weight recorded. A reference crucible was used to monitor the weight change of the crucible due to the variation of the temperature. The sample was heated at a rate of 20° C./min and the weight loss of the sample with increasing temperature was recorded at intervals of 0.125 s/point. The relative weight percent change was calculated by using the weight loss divided by the total original weight of the sample.

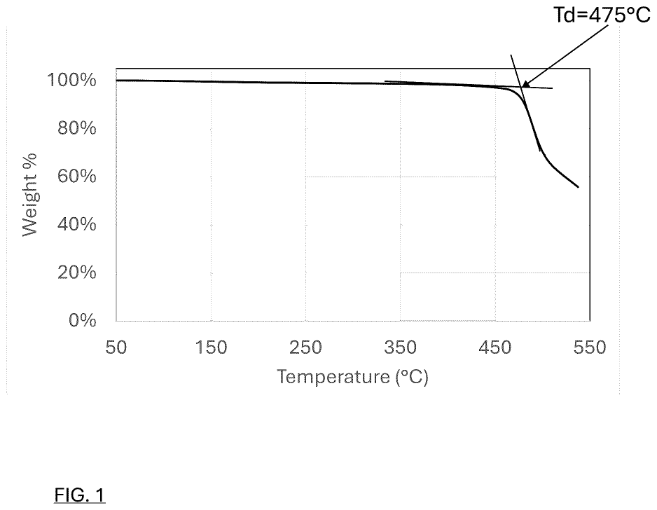

The dynamic TGA curves for the photo-cured layers of samples S3 and C3 were measured. The TGA curves showed that sample S3 had a better thermal stability compared to sample C3. The onset degradation temperature for sample S3 was 475° C., while the onset degradation temperature for sample C3 was 469° C. As used herein, the onset degradation temperature relates to the temperature wherein a deflection of the TGA curve from the almost linear plateau shape is first observed, shortly before the steep decline of the mass of the sample, i.e., degradation. FIG. 1 illustrates the TGA curve for sample S3 and how the onset degradation temperature (Td) was determined.

### Isothermal Thermogravimetry:

The isothermal thermogravimetry (TGA) measurements were conducted at constant temperatures of 400° C. for about 30 minutes. The measurements were conducted with the same TGA instrument described above and also under nitrogen. For each measurement, 25-35 mg of the photo-cured sample was put in the crucible and the initial weight was recorded. The temperature was quickly raised to the aimed testing temperature of 400° C. with a rate of 90° C./min, and when the set temperature was reached, the weight loss was recorded over the time period of 30 minutes. The results showed that sample S1 had a slower weight loss than comparative sample C3 over the measured time period. While sample S1 had a weight loss of 0.012%/min, the weight loss of sample C3 was 0.045%/min.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any sub combination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A photocurable composition comprising a polymerizable material and at least one photoinitiator, wherein
the polymerizable material comprises at least one multi-functional vinylbenzene monomer in an amount of at least 30 wt % based on the total weight of the polymerizable material;
the at least one photoinitiator includes an oxime ester compound having a structure of formula (1): 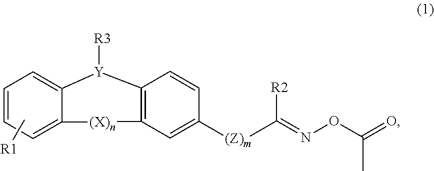
with
R1 being H, substituted or unsubstituted alkyl or aryl, 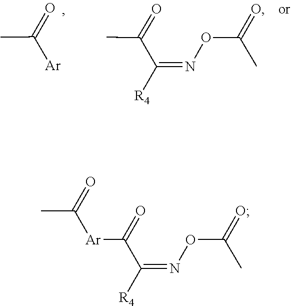
R2 being H or C1-C8 alkyl;
R3 being C₄-C₂₀ alkyl or isoalkyl;
R4 being H, or alkyl, or aryl;
X being S(═O), CH₂, C(═O), O, or NH; n being 0 or 1;
Y being N or CH₂;
Z being C(═O); m being 0 or 1.

2. The photocurable composition of claim 1, wherein the photoinitiator has a structure of formula (2): 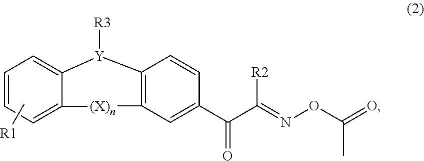
with
R1 being H, C₁-C₂₀ alkyl or isoalkyl, 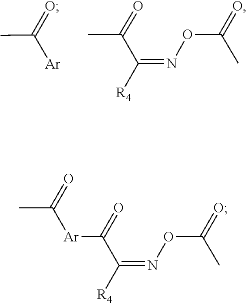
R2 being H or C1-C8 alkyl;
R3 being C4-C20 alkyl or isoalkyl;
R4 being H, or alkyl, or aryl;
Ar being aryl;
X being S(═O), CH₂, C(═O), O, or NH; n being 0 or 1;
Y being N or CH₂.

3. The photocurable composition of claim 2, wherein the oxime ester compound has a structure of formula (3):

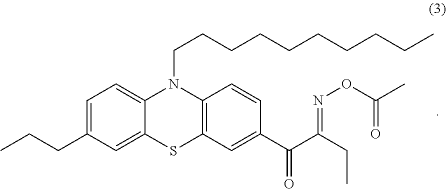 [SMILES: CCCCCCCCCCN1c2ccc(CCC)cc2Sc2cc(C(=O)/C(CC)=N/OC(C)=O)ccc21]

4. The photocurable composition of claim 2, wherein the oxime ester compound has a structure of formula (4):

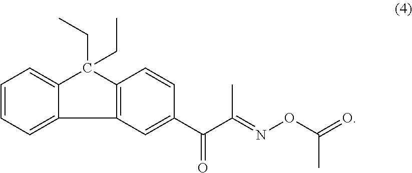 [SMILES: CCC1(CC)c2ccccc2-c2cc(C(=O)/C(C)=N/OC(C)=O)ccc21]

5. The photocurable composition of claim 1, wherein the photocurable composition is adapted that a photo-cured layer formed from the photocurable composition has a thermal shrinkage after a baking treatment at 400° C. of not greater than 4.0%, the baking treatment including 2 minutes baking of the photo-cured layer with a thickness of 450-550 nm on a stainless steel plate having a temperature of 400° C. under N₂ environment.

6. The photocurable composition of claim 1, wherein the oxime ester of formula (1) does not contain fluoride.

7. The photocurable composition of claim 1, wherein an amount of the oxime ester compound is at least 1 wt % and not greater than 7 wt % based on a total weight of the photocurable composition.

8. The photocurable composition of claim 7, wherein the amount of the oxime ester compound is at least 3 wt % based on the total weight of the photocurable composition.

9. The photocurable composition of claim 1, wherein the at least one photoinitiator further includes a photoinitiator not being an oxime ester compound.

10. The photocurable composition of claim 1, wherein an amount of the polymerizable material is at least 85 wt % based on the total weight of the photocurable composition.

11. The photocurable composition of claim 1, wherein the multi-functional vinylbenzene monomer includes at least three vinyl groups.

12. The photocurable composition of claim 10, wherein the multi-functional vinylbenzene monomer is a biphenyl compound including three vinyl groups.

13. The photocurable composition of claim 1, wherein the amount of the multi-functional vinylbenzene monomer is at least 50 wt % based on the total weight of the polymerizable material.

14. The photocurable composition of claim 1, wherein a material after photo-curing the photocurable composition has an onset degradation temperature of at least 400° C.

15. The photocurable composition of claim 1, wherein the polymerizable material further includes at least one multi-functional acrylate monomer.

16. The photocurable composition of claim 1, wherein a viscosity of the photocurable composition is not greater than 50 mPa·s.

17. A method of forming a photo-cured layer on a substrate, comprising:
applying a layer of a photocurable composition on the substrate, wherein the photocurable composition comprises a polymerizable material and at least one photoinitiator, wherein the polymerizable material comprises at least one multi-functional vinylbenzene monomer in an amount of at least 30 wt % based on the total weight of the polymerizable material, and the at least one photoinitiator includes an oxime ester compound having a structure of formula (1): 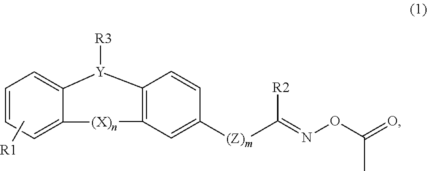
with
R1 being H, substituted or unsubstituted alkyl or aryl, 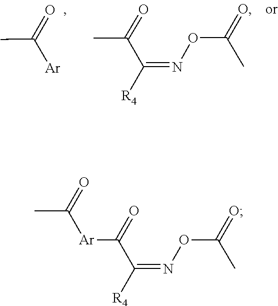
R2 being H or C1-C8 alkyl;
R3 being C₄-C₂₀ alkyl or isoalkyl;
R4 being H, or alkyl, or aryl;
X being S(═O), CH₂, C(═O), O, or NH; n being 0 or 1;
Y being N or CH₂;
Z being C(═O); m being 0 or 1;
bringing the photocurable composition into contact with a template or a superstrate;
irradiating the photocurable composition with light to form a photo-cured layer; and
removing the template or the superstrate from the photo-cured layer.

18. The method of claim 17, wherein the photo-cured layer has a thermal shrinkage after a baking treatment at 400° C. of not greater than 4.0%, the baking treatment including 2 minutes baking of the photo-cured layer having a thickness of 450 nm-550 nm under N₂ on a stainless steel plate having a temperature of 400° C.

19. The method of claim 17, wherein the photo-cured layer has an onset degradation temperature of at least 400° C.

20. A method of manufacturing an article, comprising:
applying a layer of a photocurable composition on the substrate, wherein the photocurable composition comprises a polymerizable material and at least one photoinitiator, the polymerizable material comprising at least one multi-functional vinylbenzene monomer in an amount of at least 30 wt % based on the total weight of the polymerizable material and at least one photoinitiator, the polymerizable material comprises at least one multi-functional vinylbenzene monomer in an amount of at least 30 wt % based on the total weight of the polymerizable material; and the at least one photoinitiator includes an oxime ester compound having a structure of formula (1): 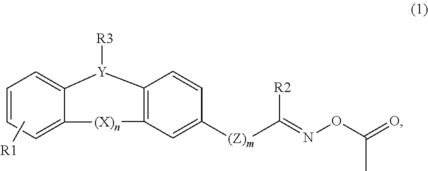
with
R1 being H, substituted or unsubstituted alkyl or aryl, 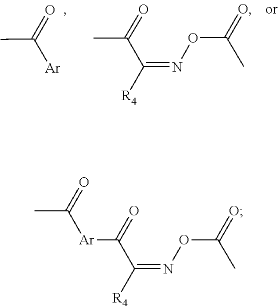
R2 being H or C1-C8 alkyl;
R3 being C₄-C₂₀ alkyl or isoalkyl;
R4 being H, or alkyl, or aryl;
X being S(═O), CH₂, C(═O), O, or NH; n being 0 or 1
Y being N or CH₂;
Z being C(═O); m being 0 or 1;
bringing the photocurable composition into contact with a template or a superstrate;
irradiating the photocurable composition with light to form a photo-cured layer;
removing the template or the superstrate from the photo-cured layer;
forming a pattern on the substrate;
processing the substrate on which the pattern has been formed in the forming; and manufacturing an article from the substrate processed in the processing.
